(19) United States
(12) Patent Application Publication
(10) Pub. No.: US 2026/0332114 A1
(43) Pub. Date: Oct. 22, 2026

(54) AMPLIFIER DEVICE AND BIASING METHOD THEREOF

(71) Applicant: REALTEK SEMICONDUCTOR CORPORATION, Hsinchu (TW)

(72) Inventor: TZU-CHIEH WEI, Hsinchu (TW)

(21) Appl. No.: 19/649,483

(22) Filed: Apr. 16, 2026

(30) Foreign Application Priority Data
Apr. 21, 2025 (TW) 114115058

(51) Int. Cl. H03F 3/45

(52) U.S. Cl. CPC H03F 3/45632; H03F 3/45183; H03F 3/45273

(57) ABSTRACT

An amplifier device includes an input pair circuit, a bias voltage generation circuit, and a current mirror circuit. The input pair circuit is configured to be biased by a bias voltage and a bias current, and to generate a first output signal and a second output signal according to a first input signal and a second input signal. The bias voltage generation circuit is configured to track, according to the bias current, an internal voltage drop variation in the input pair circuit, in order to generate the bias voltage. The current mirror circuit is coupled to the input pair circuit and the bias voltage generation circuit, and is configured to generate the bias current.

### BACKGROUND OF THE INVENTION

### 1. Field of the Invention

The present disclosure relates to an amplifier device, and more particularly to an amplifier device that adaptively generates a bias voltage and a biasing method thereof.

### 2. Description of Related Art

In an existing amplifier, a main transistor for processing a signal is biased by a voltage divider circuit, and the voltage divider circuit is generally implemented with series-coupled resistors. When the amplifier is affected by unexpected influences of various variations (for example, process variations, voltage variations, temperature variations, or the like), a bias setting in the amplifier shifts. In the above approach, the voltage divider circuit formed with resistors may only generate a fixed bias voltage, and cannot adjust the bias voltage according to the shift, such that the main transistor in the amplifier may incorrectly operate in an unexpected operating region (for example, a triode region), thereby causing performance degradation of the amplifier.

### SUMMARY OF THE INVENTION

In some aspects, one of the objects of the present disclosure is (but is not limited to) providing an amplifier device capable of adaptively generating a bias voltage and a biasing method thereof, so as to make an improvement to the prior art.

In some aspects, an amplifier device includes an input pair circuit, a bias voltage generation circuit, and a current mirror circuit. The input pair circuit is configured to be biased by a bias voltage and a bias current, and to generate a first output signal and a second output signal according to a first input signal and a second input signal. The bias voltage generation circuit is configured to track, according to the bias current, an internal voltage drop variation in the input pair circuit, in order to generate the bias voltage. The current mirror circuit is coupled to the input pair circuit and the bias voltage generation circuit, and is configured to generate the bias current.

In some aspects, a biasing method, which is applied to an amplifier device, includes the following operations: biasing an input pair circuit in the amplifier device through a bias voltage and a bias current, such that the input pair circuit generates a first output signal and a second output signal according to a first input signal and a second input signal; tracking, by a bias voltage generation circuit in the amplifier device, according to the bias current, an internal voltage drop variation in the input pair circuit, in order to generate the bias voltage; and generating, by a current mirror circuit in the amplifier device, the bias current, wherein the current mirror circuit is coupled to the input pair circuit and the bias voltage generation circuit.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 is a schematic diagram of an amplifier device according to some embodiments of the present disclosure.

FIG. 2 is a circuit schematic diagram of the amplifier device of FIG. 1 according to some embodiments of the present disclosure.

FIG. 3 is a flowchart of a biasing method according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuitry” may be a system formed with one or more circuits, and the term “circuit” may indicate an object, which is formed with one or more transistors and/or one or more active/passive elements according to a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

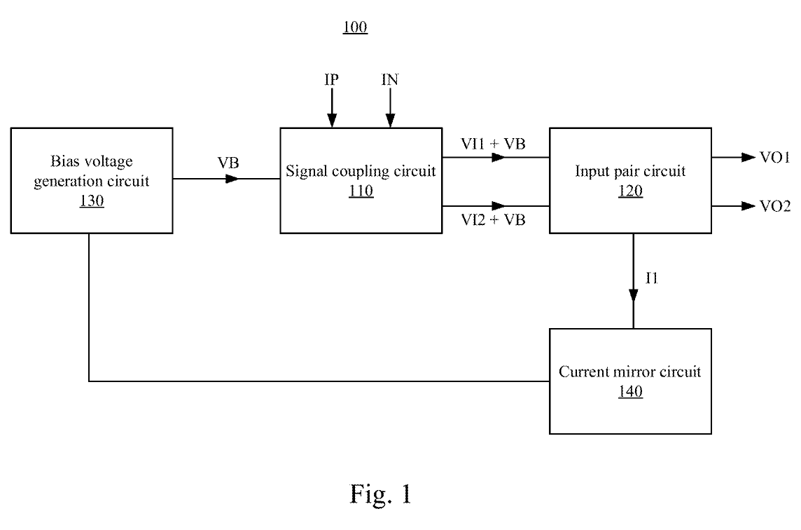

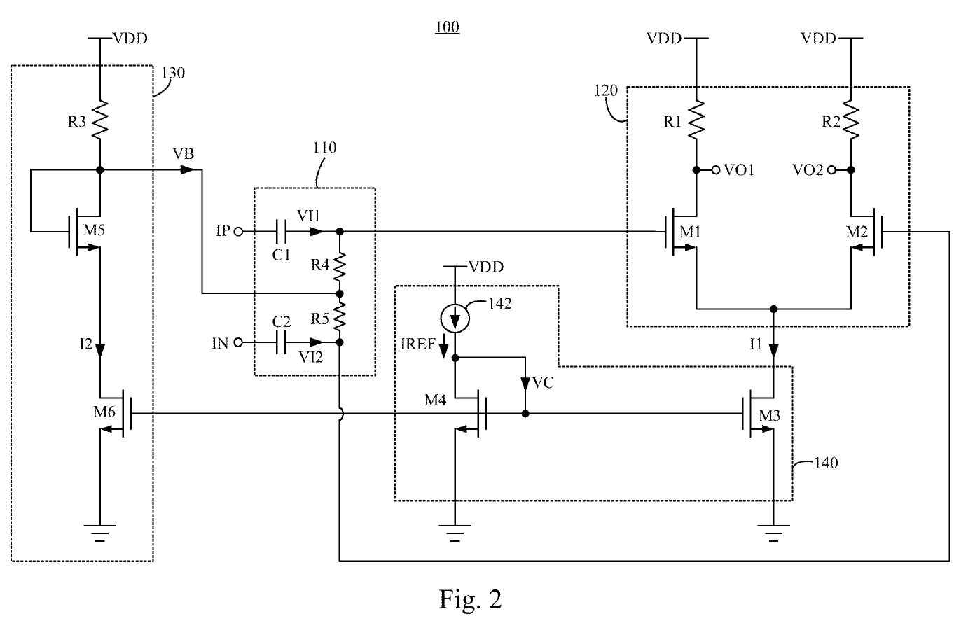

FIG. 1 is a schematic diagram of an amplifier device 100 according to some embodiments of the present disclosure. In some embodiments, the amplifier device 100 includes a signal coupling circuit 110, an input pair circuit 120, a bias voltage generation circuit 130, and a current mirror circuit 140. The signal coupling circuit 110 is configured to couple an AC signal component (hereinafter referred to as an input signal VI1) in a signal IP to the input pair circuit 120, and to couple an AC signal component (hereinafter referred to as an input signal VI2) in a signal IN to the input pair circuit 120. The input pair circuit 120 is configured to be biased by a bias voltage VB and a bias current I1, and to generate an output signal VO1 and an output signal VO2 according to the input signal VI1 and the input signal VI2. The bias voltage generation circuit 130 is configured to track, according to the bias current I1, an internal voltage drop variation in the input pair circuit 120, in order to generate the aforementioned bias voltage VB. In some embodiments, the bias voltage generation circuit 130 is further configured to transmit the bias voltage VB to the input pair circuit 120 through the signal coupling circuit 110. Details in this regard will be given later with reference to FIG. 2. The current mirror circuit 140 is coupled to the input pair circuit 120 and the bias voltage generation circuit 130, and is configured to generate the aforementioned bias current I1.

In some embodiments, based on a replica biasing technique, the bias voltage generation circuit 130 may be configured to simulate at least a part of a connection relationship and related circuit settings between the input pair circuit 120 and the current mirror circuit 140, such that the bias voltage generation circuit 130 tracks, according to the bias current I1, the internal voltage drop variation, in order to generate the bias voltage VB. In such a manner, under an influence of mismatch caused by unexpected factors, the bias voltage VB still causes transistors (for example, the transistor M1 and the transistor M2 of FIG. 2) in the input pair circuit 120 to be fixedly operated in a saturation region, such that the input pair circuit 120 may continuously correctly generate the output signal VO1 and the output signal VO2 according to the input signal VI1 and the input signal VI2.

FIG. 2 is a circuit schematic diagram of the amplifier device 100 of FIG. 1 according to some embodiments of the present disclosure. In the example, the input pair circuit 120 includes a transistor M1, a transistor M2, a resistor R1, and a resistor R2. The transistor M1 is coupled between the resistor R1 and the current mirror circuit 140, and is biased by the bias voltage VB and the bias current I1 to generate the output signal VO1 according to the input signal VI1. Similarly, the transistor M2 is coupled between the resistor R2 and the current mirror circuit 140, and is biased by the bias voltage VB and the bias current I1 to generate the output signal VO2 according to the input signal VI2.

In greater detail, a first terminal of the resistor R1 and a first terminal of the resistor R2 receive a supply voltage VDD, a second terminal of the resistor R1 is coupled to a first terminal of the transistor M1 (e.g., a drain) to provide the output signal VO1, and a second terminal of the resistor R2 is coupled to a first terminal of the transistor M2 to provide the output signal VO2. A second terminal of the transistor M1 (e.g., a source) and a second terminal of the transistor M2 are coupled to the current mirror circuit 140, a control terminal of the transistor M1 (e.g., a gate) receives the input signal VI1, and a control terminal of the transistor M2 receives the input signal VI2. In some embodiments, the transistor M1 and the transistor M2 may be configured as a differential input pair. For example, the transistor M1 and the transistor M2 may have an identical size, and may be configured to process signals having opposite phases (e.g., the input signal VI1 and the input signal VI2).

The current mirror circuit 140 includes a transistor M3, a transistor M4, and a current source circuit 142. The current source circuit 142 receives the supply voltage VDD and is configured to provide a reference current IREF. A first terminal of the transistor M3 is coupled to the second terminal of the transistor M1 and the second terminal of the transistor M2, and drains the bias current I1 from the transistor M1 and the transistor M2, such that the transistor M3 biases the transistor M1 and the transistor M2. A control terminal of the transistor M3 receives a control voltage VC, such that the transistor M3 may generate the bias current I1 according to the control voltage VC. A first terminal and a control terminal of the transistor M4 are coupled to the current source circuit 142 to receive the reference current IREF, and accordingly generate the control voltage VC. A second terminal of the transistor M3 and a second terminal of the transistor M4 are coupled to ground. The current source circuit 142 receives the supply voltage VDD, and accordingly provides the reference current IREF, to bias the transistor M4.

The bias voltage generation circuit 130 includes a resistor R3, a transistor M5, and a transistor M6. A first terminal of the resistor R3 receives the supply voltage VDD, and a second terminal of the resistor R3 is coupled to a first terminal of the transistor M5 to provide the bias voltage VB. A second terminal and a control terminal of the transistor M5 are coupled to a first terminal of the transistor M6. With the above arrangement, the transistor M5 is coupled to the resistor R3, and may be configured as a diode-connected transistor. Thus, the transistor M5 is fixedly operated in a saturation region, thereby generating a corresponding bias voltage VB. A control terminal of the transistor M6 is coupled to a control terminal of the transistor M4, to receive the control voltage VC, and a second terminal of the transistor M6 is coupled to ground. The transistor M6 operates as a current source according to the control voltage VC, to bias the transistor M5.

As described above, the bias voltage generation circuit 130 may be configured to simulate at least a part of a connection relationship and related circuit settings between the input pair circuit 120 and the current mirror circuit 140, such that the bias voltage generation circuit 130 tracks an internal voltage drop variation in the input pair circuit 120 according to the bias current I1. For example, a resistance value of the resistor R3 may be set to be about equal to a resistance value of the resistor R1, the transistor M5 and the transistor M1 may have substantially identical sizes (for example, may have an identical width-to-length ratio (i.e., aspect ratio)), the transistor M6 and the transistor M4 may have substantially identical sizes, and a size of the transistor M6 (or the transistor M4) is one half of a size of the transistor M3, that is, a ratio between a width-to-length ratio of the transistor M6 (or the transistor M4) and a width-to-length ratio of the transistor M3 is about 1:2. Thus, a ratio between the reference current IREF and the bias current I1 is about 1:2, such that a current flowing through the transistor M1 is about one half of the bias current I1 (that is, a ratio between the current flowing through the transistor M1 and the bias current I1 is about 1:2), and a current I2 flowing through the transistor M4 and the transistor M6 is also about one half of the bias current I1 (that is, a ratio between the current I2 and the bias current I1 is about 1:2). Thus, when the bias current I1 shifts due to unexpected variations, the current mirror circuit 140 adjusts the control voltage VC accordingly, such that the current I2 and the bias current I1 comply with the aforementioned ratio setting, and such that the bias voltage generation circuit 130 generates a corresponding bias voltage VB, to continuously bias the transistor M1 and the transistor M2 in a saturation region.

In other words, in this embodiment, the bias voltage generation circuit 130 may be configured to simulate a connection relationship and related circuit settings between the resistor R1, the transistor M1, and the transistor M3, in order to generate a corresponding bias voltage VB according to the bias current I1. When a corresponding voltage difference occurs between the first terminal and the second terminal of the transistor M3 due to a shift of the bias current I1, a voltage across the first terminal and the second terminal of the transistor M1 changes accordingly (that is, the aforementioned internal voltage drop variation). With the above arrangement, the bias voltage generation circuit 130 may detect the aforementioned internal voltage drop variation, in order to generate a more accurate bias voltage VB in real time according to the current I2 and the bias current I1, such that the transistor M1 and the transistor M2 may continuously and correctly operate in a saturation region. Similarly, the bias voltage generation circuit 130 may also simulate a connection relationship and related circuit settings between the resistor R2, the transistor M2, and the transistor M3, in order to generate a corresponding bias voltage VB.

The signal coupling circuit 110 includes a capacitor C1, a capacitor C2, a resistor R4, and a resistor R5. The resistor R4 and the resistor R5 are series-coupled between the capacitor C1 and the capacitor C2, and the bias voltage generation circuit 130 may transmit the bias voltage VB to the input pair circuit 120 through the resistor R4 and the resistor R5.

In greater detail, a first terminal of the capacitor C1 receives the signal IP, and a second terminal of the capacitor C1 outputs the input signal VI1 to the control terminal of the transistor M1. The capacitor C1 may operate as an AC coupling circuit, to output an AC signal component in the signal IP as the input signal VI1. Similarly, a first terminal of the capacitor C2 receives the signal IN, and a second terminal of the capacitor C2 outputs the input signal VI2 to the control terminal of the transistor M2. The capacitor C2 may operate as an AC coupling circuit, to output an AC signal component in the signal IN as the input signal VI2. A first terminal of the resistor R4 is coupled to the second terminal of the capacitor C1, a second terminal of the resistor R4 is coupled to a first terminal of the resistor R5 and is coupled to the bias voltage generation circuit 130 to receive the bias voltage VB, and a second terminal of the resistor R5 is coupled to the second terminal of the capacitor C2. With the above arrangement, the bias voltage generation circuit 130 may transmit the bias voltage VB to the control terminal of the transistor M1 through the resistor R4, to bias the transistor M1. Similarly, the bias voltage generation circuit 130 may transmit the bias voltage VB to the control terminal of the transistor M2 through the resistor R5, to bias the transistor M2. Equivalently, a signal on the second terminal of the capacitor C1 may be a superposition of the input signal VI1 and the bias voltage VB, and a signal on the second terminal of the capacitor C2 may be a superposition of the input signal VI2 and the bias voltage VB. In some embodiments, each of the resistor R4 and the resistor R5 has a sufficiently high resistance value, to increase an input signal range. In some embodiments, the resistor R4, the resistor R5, the capacitor C1, and the capacitor C2 form a high-pass filter. The capacitor C1, the capacitor C2, the transistor M1, and the transistor M2 form a high impedance (that is, the capacitor C1, the capacitor C2, a gate of the transistor M1, and a gate of the transistor M2 form the high impedance), thereby not consuming a DC (direct current) current.

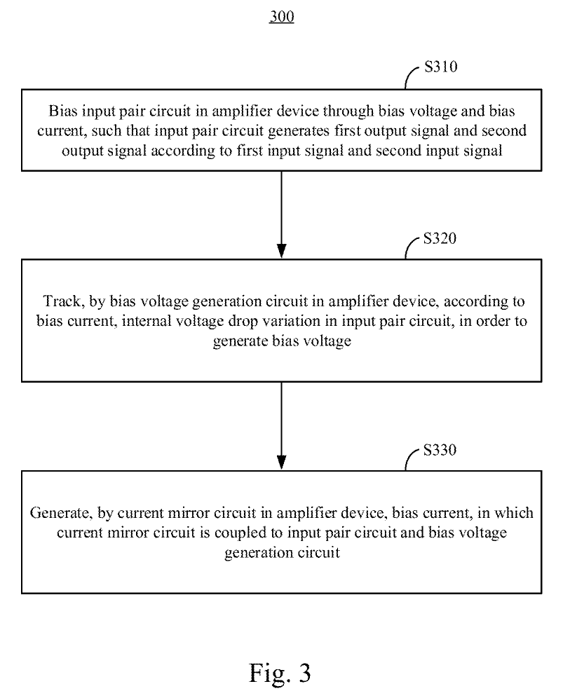

FIG. 3 is a flowchart of a biasing method 300 according to some embodiments of the present disclosure. In different embodiments, the biasing method 300 may be applicable to the amplifier device 100 of FIGS. 1 or 2, but the present disclosure is not limited thereto.

In operation S310, an input pair circuit in the amplifier device is biased through a bias voltage and a bias current, such that the input pair circuit generates a first output signal and a second output signal according to a first input signal and a second input signal. In operation S320, a bias voltage generation circuit in the amplifier device tracks, according to the bias current, an internal voltage drop variation in the input pair circuit, in order to generate the bias voltage. In operation S330, a current mirror circuit in the amplifier device generates the bias current, in which the current mirror circuit is coupled to the input pair circuit and the bias voltage generation circuit.

Related operations of the biasing method 300 may be understood with reference to description of the above embodiments, and related operations are not repeated herein. Operations related to the biasing method 300 may be understood with reference to the descriptions of the above embodiments and thus will not be repeated herein. Operations in the biasing method 300 include exemplary operations, but the operations in the biasing method 300 are not necessarily performed in the order described above. Operations in the biasing method 300 may be added, replaced, changed order, and/or eliminated, or one or more operations in the biasing method 300 may be executed simultaneously or partially simultaneously as appropriate, in accordance with the spirit and scope of various embodiments of the present disclosure.

As described above, an amplifier device and a biasing method thereof provided in some embodiments of the present disclosure may adaptively generate a bias voltage, thereby preventing the amplifier device from operating in an incorrect operating region due to unexpected influences.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of present disclosure are all consequently viewed as being embraced by the scope of the present disclosure.

What is claimed is:

1. An amplifier device, comprising:
an input pair circuit, configured to be biased by a bias voltage and a bias current, and configured to generate a first output signal and a second output signal according to a first input signal and a second input signal;
a bias voltage generation circuit, configured to track, according to the bias current, an internal voltage drop variation in the input pair circuit, in order to generate the bias voltage; and
a current mirror circuit, coupled to the input pair circuit and the bias voltage generation circuit, and configured to generate the bias current.

2. The amplifier device of claim 1, wherein the bias voltage generation circuit is configured to simulate a part of a connection relationship between the input pair circuit and the current mirror circuit, such that the bias voltage generation circuit tracks the internal voltage drop variation according to the bias current to generate the bias voltage.

3. The amplifier device of claim 1, wherein the bias voltage generation circuit comprises:
a resistor;
a first transistor, coupled to the resistor, and configured as a diode-connected transistor, to generate the bias voltage; and
a second transistor, coupled to the first transistor, and configured to bias the first transistor according to a control voltage,
wherein the current mirror circuit is further configured to generate the bias current and the control voltage according to a reference current.

4. The amplifier device of claim 3, wherein a first terminal and a control terminal of the first transistor are coupled to the resistor and are configured to output the bias voltage, a second terminal of the first transistor is coupled to a first terminal of the second transistor, a second terminal of the second transistor is coupled to ground, and a control terminal of the second transistor receives the control voltage.

5. The amplifier device of claim 3, wherein a ratio between the reference current and the bias current is 1:2.

6. The amplifier device of claim 3, wherein a ratio between a current flowing through the first transistor and the bias current is 1:2.

7. The amplifier device of claim 1, wherein the input pair circuit comprises:
a first resistor;
a first transistor, coupled between the first resistor and the current mirror circuit, and configured to be biased by the bias voltage and the bias current to generate the first output signal according to the first input signal;
a second resistor; and
a second transistor, coupled between the second resistor and the current mirror circuit, and configured to be biased by the bias voltage and the bias current to generate the second output signal according to the second input signal.

8. The amplifier device of claim 7, wherein the bias voltage is configured to cause the first transistor and the second transistor to be fixedly operated in a saturation region.

9. The amplifier device of claim 7, wherein the bias voltage generation circuit is configured to simulate a connection relationship between the first resistor, the first transistor, and the current mirror circuit, such that the bias voltage generation circuit tracks the internal voltage drop variation according to the bias current to generate the bias voltage.

10. The amplifier device of claim 1, further comprising:
a first capacitor, configured to couple the first input signal to the input pair circuit;
a second capacitor, configured to couple the second input signal to the input pair circuit; and
a plurality of resistors, series-coupled between the first capacitor and the second capacitor,
wherein the bias voltage generation circuit is further configured to transmit the bias voltage to the input pair circuit through the plurality of resistors.

11. A biasing method, applied to an amplifier device, the biasing method comprising:
biasing an input pair circuit in the amplifier device through a bias voltage and a bias current, such that the input pair circuit generates a first output signal and a second output signal according to a first input signal and a second input signal;
tracking, by a bias voltage generation circuit in the amplifier device, according to the bias current, an internal voltage drop variation in the input pair circuit, in order to generate the bias voltage; and
generating, by a current mirror circuit in the amplifier device, the bias current, wherein the current mirror circuit is coupled to the input pair circuit and the bias voltage generation circuit.

12. The biasing method of claim 11, wherein tracking, by the bias voltage generation circuit, according to the bias current, the internal voltage drop variation, in order to generate the bias voltage comprises:
simulating, by the bias voltage generation circuit, a part of a connection relationship between the input pair circuit and the current mirror circuit, such that the bias voltage generation circuit tracks the internal voltage drop variation according to the bias current to generate the bias voltage.

13. The biasing method of claim 11, wherein the bias voltage is configured to cause transistors in the input pair circuit that receive the first input signal and the second input signal to be fixedly operated in a saturation region.
